(19) United States
(12) Patent Application Publication
(10) Pub. No.: US 2026/0324348 A1
(43) Pub. Date: Oct. 15, 2026

(54) TEACHING SUBSTRATE HANDLING IN SEMICONDUCTOR PROCESSING SYSTEMS USING THERMAL IMAGING

(71) Applicant: ASM IP Holding B.V., Almere (NL)

(72) Inventors: Pinyi Wu, Tempe, AZ (US); Salam Harb, Scottsdale, AZ (US); Ananthakrishnan Bhagyarajan, Tokyo (JP)

(21) Appl. No.: 19/644,020

(22) Filed: Apr. 10, 2026

Related U.S. Application Data
(60) Provisional application No. 63/789,074, filed on Apr. 15, 2025.

(51) Int. Cl. H10P 72/00; G01J 5/00; G06T 7/73; G06T 7/77; H10P 72/30; H10P 72/76

(52) U.S. Cl. CPC H10P 72/0606; G01J 5/0007; G06T 7/73; G06T 7/77; H10P 72/3302; H10P 72/7602; H10P 72/7612; G01J 2005/0077; G06T 2207/10024; G06T 2207/10048

(57) ABSTRACT

Semiconductor processing systems and methods of substrate handling are described here. A substrate is provided in a reaction chamber, and one or more processing conditions (e.g., high-temperature level or high-pressure level) are applied to the reaction chamber. The substrate is supported by a plurality of lift pins disposed inside the reaction chamber, and each lift pin of the plurality of lift pins is in contact with the substrate at a contact point on the substrate. A thermal image of the substrate is captured with a thermal camera, and contact points for each of the lift pins are determined by analyzing the thermal image. Future handling of the substrates within the reaction chamber by the semiconductor processing system is configured based on the determined contact points of the lift pins.

### CROSS-REFERENCE TO RELATED APPLICATIONS

This application claims priority to U.S. Provisional Patent Application Ser. No. 63/789,074 filed Apr. 15, 2025 titled TEACHING SUBSTRATE HANDLING IN SEMICONDUCTOR PROCESSING SYSTEMS USING THERMAL IMAGING, the disclosure of which is hereby incorporated by reference in its entirety.

### FIELD

The present disclosure relates generally to the field of semiconductor processing methods and systems and to the field of device and integrated circuit manufacture. More particularly, the present disclosure generally relates to teaching substrate handling in semiconductor processing systems.

### BACKGROUND

Semiconductor processing systems commonly employ substrate handling modules to place substrates in and retrieve substrates from reaction chambers. A substrate handling module of a semiconductor processing system generally includes a substrate handling robot for placing substrates on susceptors within the reaction chambers for processing the substrates. To accurately place and pick up substrates in the processing chambers, the substrate handling module and/or the substrate handling robot of a semiconductor processing system may need to know the locations of various components inside the reaction chambers. Coordinates may be programmed into the substrate handling robot during a setup process of the semiconductor processing system such that hand-off (e.g., pick and place) locations used by the robot are known. For example, the reaction chambers may comprise one or more susceptors. Various locations of the susceptor (e.g., the center of the stage) may be programmed into the substrate handling robot. Typically, the setup process may be performed by a technician or a field service engineer while the reaction chamber is cold (e.g., at room temperature).

However, once the reaction chamber is under vacuum or raised to a higher temperature, coordinates of a specific location (e.g., the center of the susceptor) within the reaction chamber may have moved, or a substrate located on the susceptor may move. Since the uniformity of films grown on a substrate can be influenced by the placement of the substrate in the susceptor, it is typically necessary to teach the substrate handling robot the pressing location of each susceptor in the reaction chamber of various processing conditions (e.g., various processing temperature and/or chamber pressures). Accurate placement of a substrate to a specific location during process conditions is desired to decrease errors incurred during the processing of the substrate and to achieve smaller manufacturing variations factors for semiconductor devices and/or integrated circuits.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to teaching locations of lift pins present in reaction chambers to a controller and/or a substrate handling robot of a semiconductor processing system such that the controller and/or the substrate handling robot may accurately place substrates in the reaction chamber during various processing conditions (e.g., elevated temperature, elevated pressure, vacuum, etc.).

In accordance with examples of the disclosure, a method for teaching substrate handling in a semiconductor processing system may comprise providing a substrate inside a reaction chamber comprising a plurality of lift pins, where each lift pin of the plurality of lift pins is in contact with the substrate at a contact point on the substrate. The method may further comprise applying one or more processing conditions to the reaction chamber and capturing a thermal image of the substrate via a thermal camera. The method may further comprise training, based on the contact point for each lift pin of the plurality of lift pins, the substrate handling robot to place another substrate in the reaction chamber.

In accordance with examples of the disclosure, the capturing of the thermal image of the substrate may comprise transferring the substrate from the reaction chamber to a substrate handling module of the semiconductor processing system and capturing, in the substrate handling module, the thermal image.

In accordance with examples of the disclosure, capturing the thermal image of the substrate may comprise transferring the substrate from the reaction chamber to a front-end module of the semiconductor processing system and capturing, in the front-end module, the thermal image.

In accordance with examples of the disclosure, capturing the thermal image of the substrate may comprise selecting, based on a thermal diffusivity of the substrate, a second chamber in the semiconductor processing system, transferring the substrate from the reaction chamber to the second chamber, and capturing, in the second chamber, the thermal image.

In accordance with examples of the disclosure, the thermal camera may be disposed above an upper surface of the substrate. In accordance with examples of the disclosure, the thermal camera may be disposed below a lower surface of the substrate.

In accordance with examples of the disclosure, the thermal image of the substrate may comprise a plurality of pixels that corresponds to a plurality of portions on the substrate, and each pixel of the plurality of pixels may represent a temperature of a corresponding location of the plurality of portions.

In accordance with examples of the disclosure, determining the contact point for each lift pin of the plurality of lift pins may comprise binarizing the thermal image to identify a cluster of pixels, from the plurality of pixels, associated with the lift pin, selecting, from the cluster of pixels, a pixel representing a highest temperature from temperatures represented by the cluster of pixels, and determining the contact point of the lift pin to be the corresponding location, of the plurality of portions, associated with the selected pixel.

In accordance with examples of the disclosure, the thermal image may comprise a color image. In accordance with examples of the disclosure, determining the contact point for each lift pin of the plurality of lift pins comprises converting the color image to a grayscale image, binarizing the grayscale image to identify a cluster of pixels, from the plurality of pixels, associated with the lift pin, selecting, from the cluster of pixels, a pixel representing a highest temperature among temperatures represented by the cluster of pixels, and determining the contact point of the lift pin to be the corresponding location, of the plurality of portions, associated with the selected pixel.

In accordance with examples of the disclosure, determining the contact point for each lift pin of the plurality of lift pins may comprise Gaussian fitting at least a portion of the plurality of pixels to identify a peak pixel associated with the lift pin and determining the contact point of the lift pin to be the corresponding location of the plurality of portions, associated with the identified peak pixel.

In accordance with examples of the disclosure, the contact point of each lift pin of the plurality of lift pins may comprise x and y coordinates on an upper surface or a lower surface of the substrate.

In accordance with examples of the disclosure, each lift pin of the plurality of lift pins may be in contact with the substrate via a contact tab of the lift pin, and the contact point of each lift pin of the plurality of lift pins may comprise a center point of the contact tab of the lift pin.

In accordance with examples of the disclosure, the one or more processing conditions may comprise at least one of a temperature level inside the reaction chamber or a pressure level inside the reaction chamber.

In accordance with examples of the disclosure, a semiconductor processing system may comprise a reaction chamber comprising a plurality of lift pins, a substrate handling module, a thermal camera coupled to the substrate handling module, a substrate handling robot configured to transfer substrates from and to the reaction chamber, and one or more controllers. The one or more controllers may be configured to provide a substrate inside the reaction chamber, where each lift pin of the plurality of lift pins is in contact with the substrate at a contact point on the substrate. The one or more controllers may be further configured to apply one or more processing conditions to the reaction chamber, transfer the substrate from the reaction chamber to the substrate handling module, capture, in the substrate handling module and via the thermal camera, a thermal image of the substrate, determine, based on analyzing the thermal image, the contact point for each lift pin of the plurality of lift pins, and train, based on the contact point for each lift pin of the plurality of lift pins, the substrate handling robot to place another substrate in the reaction chamber.

In accordance with examples of the disclosure, the thermal image of the substrate may comprise a plurality of pixels that corresponds to a plurality of portions on the substrate, and each pixel of the plurality of pixels represents a temperature of a corresponding location of the plurality of portions.

In accordance with examples of the disclosure, the one or more controllers may be configured to determine the contact point for each lift pin of the plurality of lift pins by binarizing a color version of the thermal image or a grayscale version of the thermal image to identify a cluster of pixels, from the plurality of pixels, associated with the lift pin; selecting, from the cluster of pixels, a pixel representing a highest temperature among temperatures represented by the cluster of pixels, and determining the contact point of the lift pin to be the corresponding location, of the plurality of portions, associated with the selected pixel.

In accordance with examples of the disclosure, the one or more controllers may be configured to determine the contact point for each lift pin of the plurality of lift pins by Gaussian fitting at least a portion of the plurality of pixels to identify a peak pixel associated with the lift pin and determining the contact point of the lift pin to be the corresponding location of the plurality of portions, associated with the identified peak pixel.

In accordance with examples of the disclosure, the thermal camera may be disposed above an upper surface of the substrate.

In accordance with examples of the disclosure, a semiconductor processing system may comprise a reaction chamber comprising a plurality of lift pins, a front-end module, a thermal camera coupled to the front-end module, a substrate handling robot configured to transfer substrates from and to the reaction chamber, and one or more controllers. The one or more controllers may be configured to provide a substrate inside the reaction chamber, wherein each lift pin of the plurality of lift pins is in contact with the substrate at a contact point on the substrate, apply one or more processing conditions to the reaction chamber, transfer the substrate from the reaction chamber to the front-end module, capture, in the front-end module and via the thermal camera, a thermal image of the substrate, determine, based on analyzing the thermal image, the contact point for each lift pin of the plurality of lift pins, and train, based on the contact point for each lift pin of the plurality of lift pins, the substrate handling robot to place another substrate in the reaction chamber.

In accordance with examples of the disclosure, the thermal image of the substrate may comprise a plurality of pixels that corresponds to a plurality of portions on the substrate, and each pixel of the plurality of pixels may represent a temperature of a corresponding location of the plurality of portions. The one or more controllers may be configured to determine the contact point for each lift pin of the plurality of lift pins by Gaussian fitting at least a portion of the plurality of pixels to identify a peak pixel associated with the lift pin and determining the contact point of the lift pin to be the corresponding location of the plurality of portions, associated with the identified peak pixel.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1A illustrates an example semiconductor processing system in accordance with one or more embodiments of the disclosure.

FIG. 1B illustrates a cross-sectional side view of the example semiconductor processing system in FIG. 1A, in accordance with one or more embodiments of the disclosure.

FIGS. 2A and 2B are cross-sectional side views of a reaction chamber in accordance with one or more embodiments of the disclosure.

FIG. 2C illustrates an example lift pin in accordance with one or more embodiments of the disclosure.

FIG. 3 is a flowchart illustrating an example method of teaching substrate handling in a semiconductor processing system in accordance with one or more embodiments of the disclosure.

FIG. 4 is a flowchart illustrating an example method of determining contact points between a substrate and lift pins in accordance with one or more embodiments of the disclosure.

FIGS. 5A, 5B, and 5C illustrate example images during various stages of the example method of FIG. 4 in accordance with one or more embodiments of the disclosure.

FIG. 6 illustrates an example movement over time of a contact point determined by the example method of FIG. 4 in accordance with one or more embodiments of the disclosure.

FIG. 7 is a flowchart illustrating another example method of determining contact points of a substrate and lift pins in accordance with one or more embodiments of the disclosure.

FIGS. 8A, 8B, and 8C illustrate example images during various stages of the example method of FIG. 7 in accordance with one or more embodiments of the disclosure.

FIG. 9 illustrates an example movement over time of a contact point determined by the example method of FIG. 7 in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include substrates in various shapes and sizes. Substrates may be made from materials such as silicon, silicon germanium, silicon oxide, gallium arsenide, gallium nitride, and silicon carbide, for example. A continuous substrate may extend beyond the bounds of a process chamber where a deposition process occurs and may move through the process chamber such that the process continues until the end of the substrate is reached. A continuous substrate may be supplied from a continuous substrate feeding system, allowing for the manufacture and output of the continuous substrate in any appropriate form. Non-limiting examples of a continuous substrate may include a sheet, a non-woven film, a roll, a foil, a web, a flexible material, or a bundle of continuous filaments or fibers (i.e., ceramic fibers or polymer fibers). Continuous substrates may also comprise carriers or sheets upon which non-continuous substrates are mounted.

As used herein, the term “layer” can refer to any continuous or non-continuous structure and material. For example, a layer can include two-dimensional materials, three-dimensional materials, nanoparticles or even partial or full molecular layers or partial or full atomic layers or clusters of atoms and/or molecules. A layer may comprise material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc., in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover the surface of the mentioned layer. Therefore, unless the term “directly” is separately used, the term “on” or “over” will be construed to be a relative concept. Similarly, it will be understood the terms “under,” “underlying,” or “below” will be construed to be relative concepts.

The term “teach” can refer to a process of programming or calibrating substrate handling robots or controllers in a semiconductor processing system to correctly identify, position, and handle substrates in different chambers of the semiconductor processing system during semiconductor manufacturing. Teaching can be performed by entering the semiconductor processing system in a teaching mode, determining the coordinates of different components in different chambers of the semiconductor processing system, and storing these coordinates. Sensors and vision systems in the chamber may be calibrated for precise substrate detection and placement. Once verified, the coordinates of the different components are tested through test cycles, the coordinates are saved, and the system may switch to automatic mode for continuous, optimized operation. For example, as described herein, substrate handling robots in a semiconductor processing system will be programmed or calibrated with locations of lift pins in the semiconductor processing system such that the substrate handling robots can place the substrate in correct positions in reaction chambers.

In semiconductor processing systems, lift pins are mechanical components that may be used to support and elevate substrates during various stages of the manufacturing process and in various modules of the semiconductor processing systems (e.g., reaction chambers). Lift pins may be employed to raise or lower substrates in the reaction chambers of the semiconductor processing systems. Substrates may be sitting on these lift pins. After processing steps like etching or deposition in a reaction chamber, the lift pins may elevate a substrate such that the substrate may be transferred without making contact with the reaction chamber's surface or other components. The usage of lift pins may help prevent contamination or damage to the substrate.

Furthermore, lift pins may often be made from materials, such as ceramic or metal alloys, that can withstand high temperatures and aggressive chemicals. During high-temperature substrate processing, the lift pins that are in contact with a substrate may potentially leave a thermal imprint on the substrate or influence the heat distribution in the substrate. The thermal imprint may emit infrared (IR) radiation or heat, which can be detected using a thermal camera (e.g., an IR camera) positioned either above or below the substrate.

Aspects described herein may determine teaching a semiconductor processing system positions and/or location of the lift pins and/or the position of substrates when the substrates are being processed at various processing conditions (e.g., temperature level and/or pressure level). There may be a difference in the positions of the lift pins and/or the substrate when the reaction chamber is not in operation or when the reaction chamber is processing substrates. The positions of the lift pins or the substrate may be determined from the thermal imprints left on a substrate by the lift pins.

The time available to capture a clear thermal image may depend on the thermal diffusivity of the substrate material. If the substrate's thermal diffusivity is high, the available time for capturing a clear image may be short. In such cases, the thermal camera may be mounted on top of the substrate handling module. On the other hand, if the substrate has low thermal diffusivity, the thermal imprint may persist until the substrate reaches the front-end module of the semiconductor processing system. In this scenario, the IR camera can be positioned inside the front-end module to view the bottom of the substrate, which was in direct contact with the lift pins.

The systems and methods of the present disclosure may be used to teach one or more positions of the lift pins and/or susceptors within the reaction chambers to a semiconductor processing system employed for depositing films onto substrates. The teaching may be used for accurate placements of other substrates in the reaction chambers in the future.

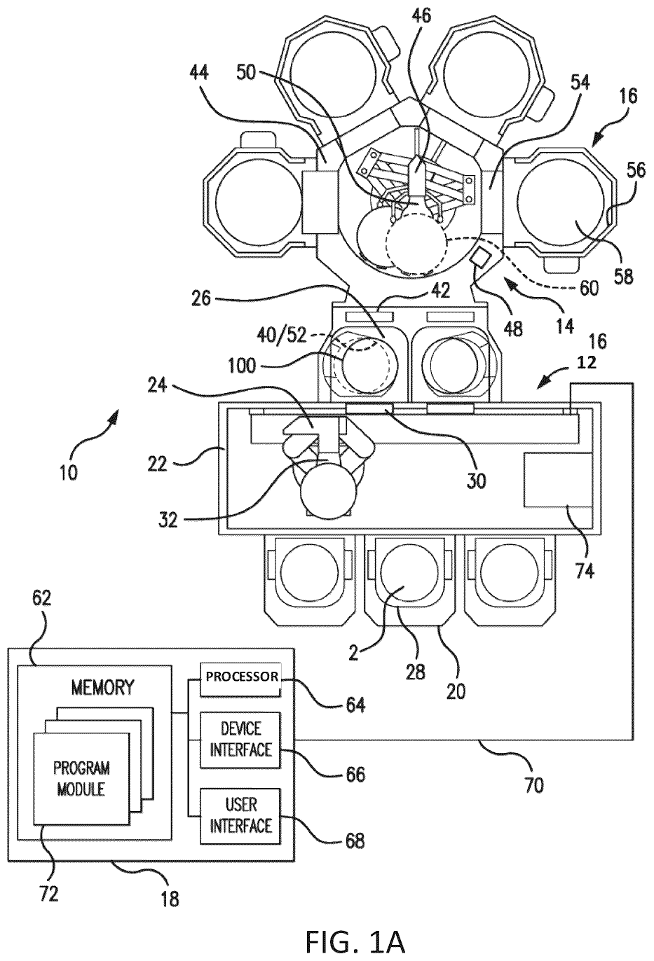

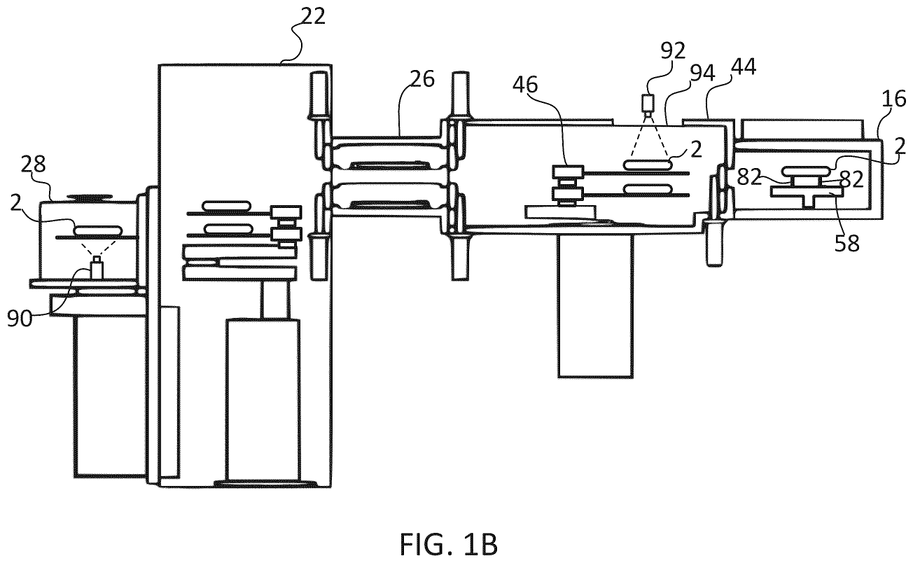

Referring to FIG. 1A, a semiconductor processing system 10 is shown. The semiconductor processing system 10 may include a front-end module 12, a substrate handling module 14, one or more reaction chambers 16, and a controller 18. The front-end module 12 may be connected to the substrate handling module 14. The substrate handling module 14 may be connected to the reaction chambers 16 and may couple the front-end module 12 to the reaction chambers 16. The reaction chambers 16 may be configured to process substrates provided to the semiconductor processing system 10, e.g., by removing and/or depositing a film onto a substrate 2, such as using a chemical vapor deposition (CVD) technique such as epitaxy or atomic layer deposition. As shown and described herein the semiconductor processing system 10 may be a cluster-type semiconductor processing system having four (4) reaction chambers. This is for illustration purposes only and is non-limiting. As will be appreciated by those of skill in the art in view of the present disclosure, other types of semiconductor processing systems, as well as semiconductor processing systems having fewer or more than four (4) reaction chambers, may also benefit from the present disclosure. Further, to the extent that the semiconductor processing system 10 is shown and described as having single-substrate reaction chambers, it is to be understood and appreciated that semiconductor processing systems having multi-substrate reaction chambers, e.g., dual-substrate, quad-substrate, and event batch-type reaction chambers, may also benefit from the present disclosure.

The front-end module 12 may include a load port 20, a front-end transfer chamber 22, a front-end transfer robot 24, and/or a load lock 26. The load port 20 may be configured to seat thereon a pod 28, e.g., a front-opening unified pod (FOUP), containing a substrate, e.g., the substrate 2, and may be connected to the front-end transfer chamber 22. The front-end transfer chamber 22 may be connected to the load lock 26 by a front-end gate valve 30. The front-end transfer chamber 22 may be connected to the load port 20 and house the front-end transfer robot 24. The front-end transfer robot 24 may include a clamp-type end effector 32 and may be movably supported within the front-end transfer chamber 22 to transport substrates between the load port 20 and the load lock 26. The load lock 26 may include a storage rack with one or more substrate slots and verification pin seats. The front-end transfer robot 24 may be configured to transport substrates between the load port 20 and the load lock 26 according to a predetermined front-end transfer robot-to-load lock transfer position 40, which may be taught to the front-end transfer robot 24, and which may further require verification (and/or update) during the service life of the semiconductor processing system 10. In certain examples, substrate 2 may be a 300-millimeter silicon substrate.

The substrate handling module 14 may include a gate valve 42, a substrate handling chamber 44, a substrate handling transfer robot 46, and/or a substrate-centering sensor 48. The gate valve 42 may connect the substrate handling chamber 44 to the load lock 26 and may be configured to provide selective communication between the substrate handling chamber 44 and the load lock 26. The substrate handling chamber 44 may connect the load lock 26 to the reaction chambers 16 and house the substrate handling transfer robot 46. The substrate handling transfer robot 46 may be movably supported within the substrate handling chamber 44. The substrate handling transfer robot 46 may include a blade-type end effector 50 and may be configured to transport substrates between the load lock 26 and the reaction chambers 16. The substrate handling transfer robot 46 may transport substrates (e.g., the substrate 2) to the load lock 26 and from the reaction chambers 16 according to a predetermined substrate handling transfer robot-to-load lock transfer position 52, which may be taught to the substrate handling transfer robot 46 during a qualification setup process, and which may require verification (and/or update) during the service life of the semiconductor processing system 10. The substrate handling transfer robot 46 may transport substrates (e.g., the substrate 2) between the load lock 26 and the reaction chambers 16 according to a predetermined substrate handling transfer robot-to-load lock transfer position 52, which may be taught to the substrate handling transfer robot 46 during a qualification setup process, and which may require verification (and/or update) during the service life of the semiconductor processing system 10.

A reaction chamber 16 may include a reaction chamber gate valve 54, a chamber body 56, and a susceptor or heater 58. The reaction chamber gate valve 54 may connect the chamber body 56 to the substrate handling chamber 44 and be configured to provide selective communication between the substrate handling chamber 44 and the chamber body 56. The chamber body 56 may be connected to the substrate handling chamber 44 and house the susceptor or heater 58. The susceptor or heater 58 may be configured to support a substrate, e.g., the substrate 2, within the chamber body 56 during processing, e.g., the removal and/or deposition of a film onto the surface of the substrate. The substrate handling transfer robot 46 may be further configured to transport substrates between the substrate handling chamber 44 and the chamber body 56 of the reaction chambers 16 according to a predetermined substrate centering position 60, which may be taught to a substrate-centering sensor 48 during a qualification setup, and which may further require verification (and/or verification) during the service life of the semiconductor processing system 10.

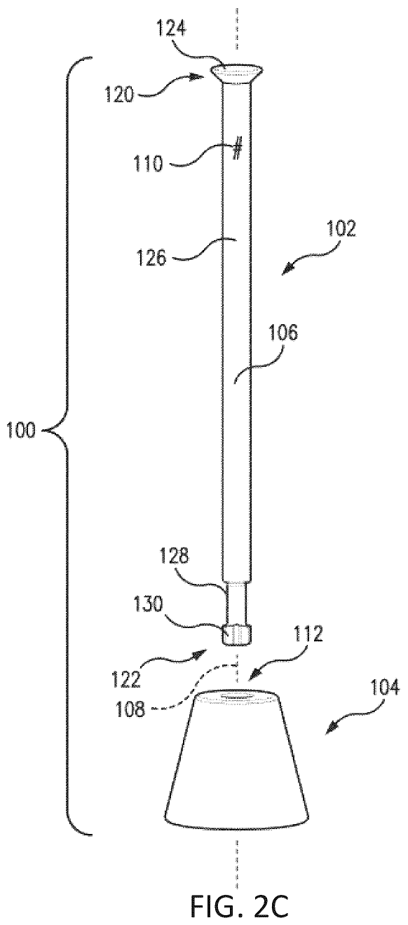

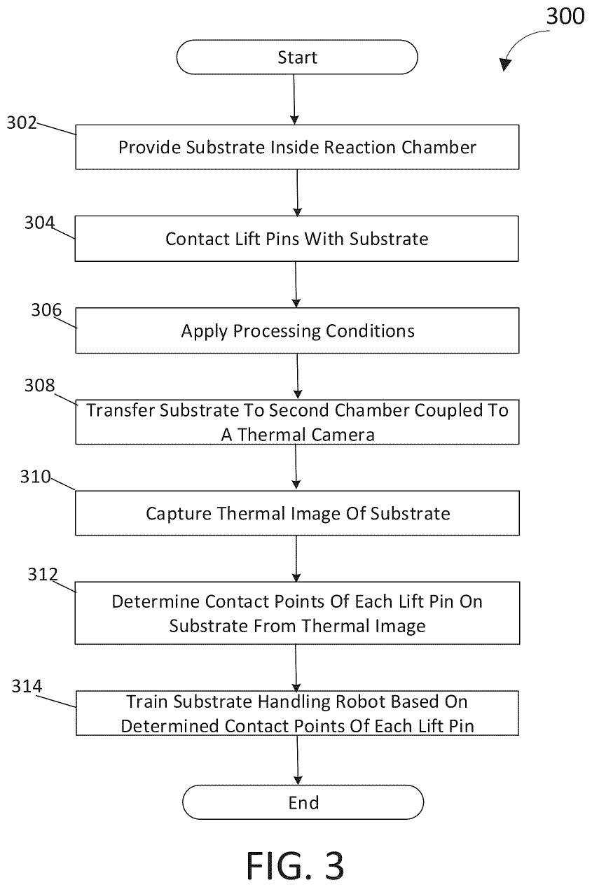

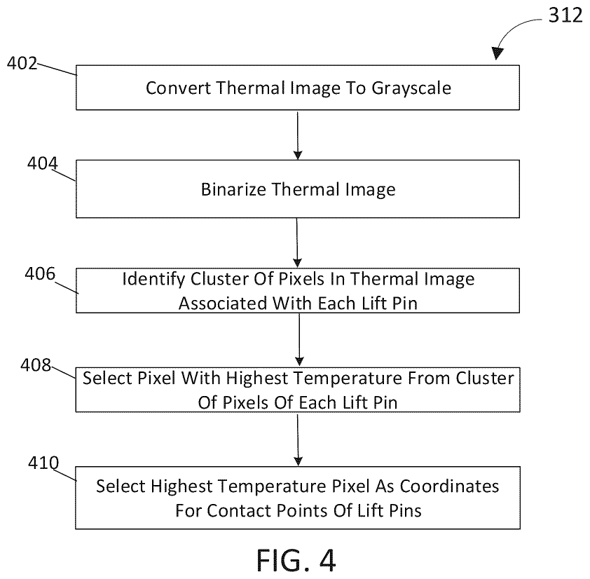

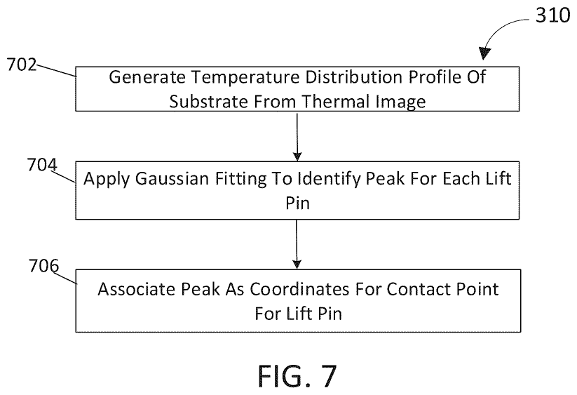

The controller 18 may be operatively connected to the semiconductor processing system 10 and may include a memory 62, a processor 64, a device interface 66, and a user interface 68. The device interface 66 may communicatively couple the processor 64 to the semiconductor processing system 10, for example, by a wired or wireless link 70. The user interface 68 may be operatively associated with the processor 64 and may be configured to receive input from a user and/or provide output to the user. The memory 62 may include a non-transitory machine-readable medium having a plurality of program modules 72 recorded thereon containing instructions that, when read by the processor 64, cause the processor 64 to execute certain operations. Among the operations are operations of method 300 (shown in FIG. 3) of teaching substrate handling in a semiconductor processing system (e.g., the semiconductor processing system 10), as will be described. The controller 18 may be configured to perform the operations of the method and/or algorithms in FIGS. 4 and 7, as described below.

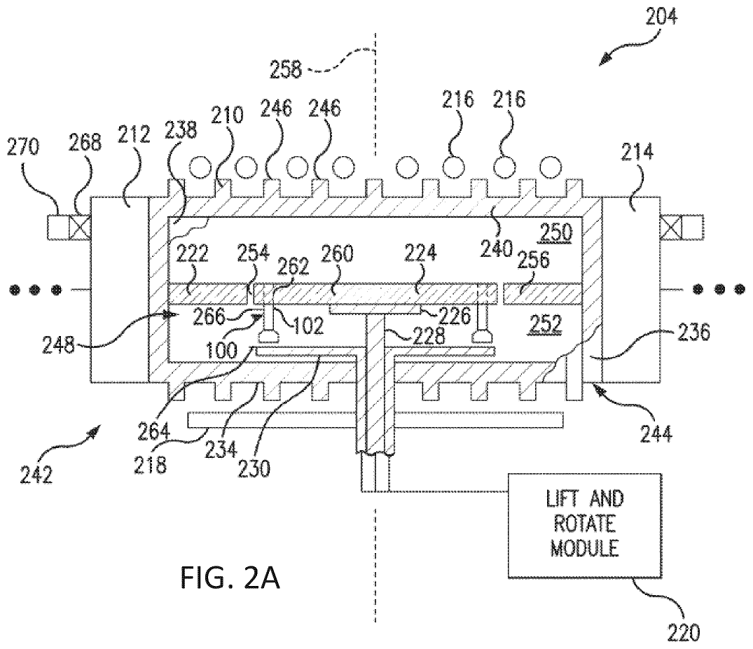

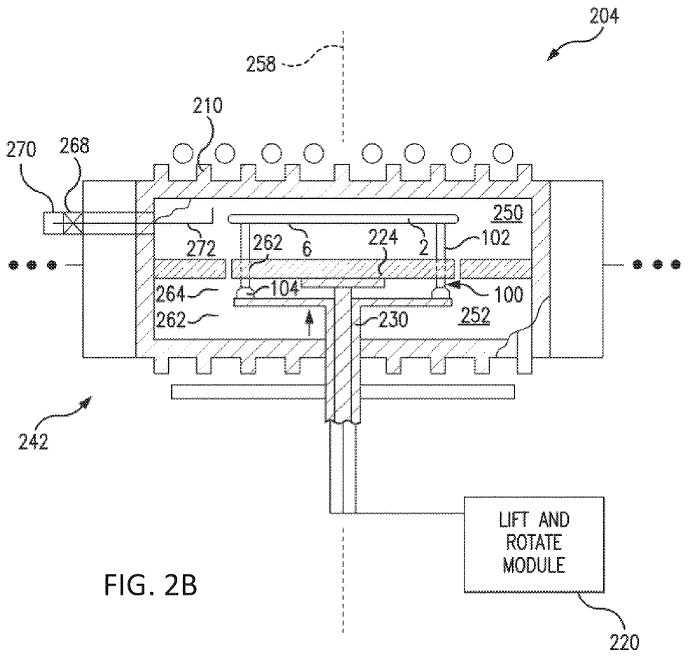

FIG. 1B illustrates a cross-sectional side view of the example semiconductor processing system 10. The substrate 2 may be positioned upon one or more lift pins present in the reaction chambers 16. The lift pins are described in more detail below with respect to FIGS. 2A, 2B, and 2C. The pod 28 may comprise a thermal camera 90. The thermal camera 90 may be configured to capture thermal images of a lower surface of the substrate 2 located in the pod 28. Additionally, or alternatively, a thermal camera 92 may be mounted on top of the substrate handling chamber 44. The thermal camera 92 may be configured to capture thermal images of the upper surface of a substrate 2 located in the substrate handling chamber 44 and being held by the substrate handling transfer robot 46. The thermal camera 92 may be configured to capture thermal images via a window 94 located on the top of the substrate handling chamber 44. In some examples, a thermal camera may also be present in the front-end transfer chamber 22 or the load lock 26, and thermal images of the substrate may be taken in any one of the two chambers.

The thermal cameras 90 and 92 (also known as infrared cameras or IR cameras) may be devices that capture infrared radiation emitted by substrates at elevated temperatures (e.g., above room temperature) and convert the captured information into a visible thermal image (e.g., a thermogram). The thermal cameras 90 and 92 may measure the temperatures of different portions of a substrate 2 in real-time without needing direct contact. The temperature of a portion of a substrate 2 may be represented by one or more pixels in the captured thermal images. The thermal images captured by the thermal cameras 90 and 92 may be color images that visually represent the temperature distribution of the substrate 2, with warmer areas appearing in different colors, typically ranging from red to white, and cooler areas appearing in shades of blue or purple. Alternatively, thermal images captured by the thermal cameras 90 and 92 may be in grayscale, where the hotter areas appear in white or lighter shades of grey, and the cooler areas appear in black or darker shades of grey.

During operation, the front-end transfer robot 24 first transports a substrate, e.g., the silicon substrate 2, to the substrate slot of the storage rack located within the load lock 26. The substrate handling transfer robot 46, in turn, may transport the substrate from the substrate slot 36 to the reaction chambers 16, wherein the substrate is seated on the susceptor or heater 58 and processed, e.g., film removed and/or film deposited onto the surface of the substrate. The processed substrate may be thereafter transported by the substrate handling transfer robot 46 to the load lock 26. Next, the front-end transfer robot 24 may transport the processed substrate from the load lock 26 to the pod 28, and the pod 28 may be thereafter removed from the load port 20.

Transport of substrates within the semiconductor processing system 10 may be according to one or more positions taught within the semiconductor processing system 10. For example, the substrate handling transfer robot 46 may further position and retrieve substrates from the reaction chambers 16 according to the predetermined substrate-centering position 60. The predetermined substrate centering position 60 at various processing conditions may be established or maintained based on thermal imprints left on the substrate 2 by the lift pins 82 in the reaction chamber 16.

With reference to FIG. 2A, an example reaction chamber 204 (e.g., reaction chambers 16 in FIGS. 1A and 1B) is shown according to an example of the present disclosure. In the illustrated example, the reaction chamber 204 may include a chamber body 210 (e.g., the chamber body 56), an injection flange 212, an exhaust flange 214, an upper heater element array 216, a lower heater element array 218, and/or a lift and rotate module 220. The reaction chamber 204 may also include a divider 222, a susceptor 224, a support member 226, a shaft member 228, a lift pin actuator 230, and/or the lift pin arrangement 100. Although shown and described herein as including certain elements and having a specific arrangement, i.e., a single-substrate crossflow arrangement with a rotating susceptor 224, it is to be understood and appreciated that the reaction chamber 204 may include other elements and/or exclude elements shown and described herein, and/or having as well as have another arrangement in other examples and remain within the scope of the present disclosure.

The chamber body 210 may extend longitudinally between an injection end 242 and a longitudinally opposite exhaust end 244. The injection flange 212 may abut the injection end 242 of the chamber body 210 and couple the precursor source 202 to the chamber body 210 to communicate the material layer precursor to an interior 248 of the chamber body 210. The exhaust flange 214 may abut the exhaust end 244 of the chamber body 210 and couple the chamber body 210 to communicate the residual precursor and/or reaction products issued by the reaction chamber 204. The chamber body 210 may have an upper wall 232, a lower wall 234, a first sidewall 236, and a second sidewall 238. The upper wall 232 may longitudinally span the injection end 242 and the exhaust end 244 of the chamber body 210. The lower wall 234 may be similar to the upper wall 232 and may be additionally spaced apart from the upper wall 232 by the interior 248 of the chamber body 210. The first sidewall 236 and the second sidewall 238 coupled the lower wall 234 to the upper wall 232 and are laterally spaced apart from one another by the interior 248 of the chamber body 210. It contemplated that the chamber body 210 be formed from a transparent material 240, e.g., a material transmissive to electromagnetic radiation within an infrared waveband, such as a ceramic material like quartz or sapphire. The chamber body 210 may have a plurality of exterior ribs 246 extending about an exterior surface of the chamber body 210 and longitudinally spaced apart from one another between the injection end 242 and the exhaust end 244 of the chamber body 210. As shown and described herein, the upper wall 232 and the lower wall 234 are substantially planar in shape. As will be appreciated by those of skill in the art in view of the present disclosure, either (or both) the upper wall 232 and the lower wall 234 may have an arcuate profile and/or a domelike shape and remain within the scope of the present disclosure.

The upper heater element array 216 may be configured to communicate radiant heat into the interior 248 of the chamber body 210, e.g., using electromagnetic radiation within an infrared waveband, and in this respect, may be supported above the chamber body 210. The upper heater element array 216 may include a plurality of heater elements, e.g., linear filament-type lamps, extending laterally between the first sidewall 236 and the second sidewall 238 of the chamber body 210 and longitudinally spaced apart from one another between the injection end 242 and the exhaust end 244 of the chamber body 210. The lower heater element array 218 may be similar to the upper heater element array 216, may be additionally supported below the lower wall 234 of the chamber body 210, and may further include a plurality of linear filament-type lamps extending longitudinally between the injection end 242 and the exhaust end 244 of the chamber body 210 and laterally spaced apart from one another between the first sidewall 236 and the second sidewall 238. Although shown and described herein as including linear lamps having a specific orientation, it is to be understood and appreciated that either (or both) the upper heater element array 216 and the lower heater element array 218 may have linear filament-type lamps with different orientations, and/or include bulb-type lamps, and remain within the scope of the present disclosure.

The divider 222 may be fixed within an interior 248 of the chamber body 210 and divides the interior 248 into an upper chamber 250 and a lower chamber 252. The divider 222 may be further formed from an opaque material 256, e.g., a material opaque to electromagnetic radiation within an infrared waveband, and that divider 222 may further define a divider aperture 254. The divider aperture 254 may fluidly couple the upper chamber 250 of the chamber body 210 to the lower chamber 252 of the chamber body 210, and the susceptor 224 may be supported for rotation R about a rotation axis 258 within the interior 248 of the chamber body 210 and at least partially within the divider aperture 254. In certain examples, the opaque material 256 may include a carbonaceous material, such as graphite and/or pyrolytic carbon. In accordance with certain examples, the opaque material 256 may include a ceramic material, such as silicon carbide, the ceramic material coating an underlying bulk carbonaceous material, or forming a bulk material defining the divider 222.

The susceptor 224 is configured to seat the substrate 2 during the deposition of the material layer 4 onto the substrate 2, and the susceptor 224 is supported within the divider aperture 254 for rotation about a rotation axis 258. The susceptor 224 may be formed from an opaque material 260, which may be similar or differ in composition from that of the opaque material 256 forming the divider 222. It is also contemplated that the susceptor 224 may include a susceptor structure, and that the susceptor 224 may be fixed in rotation R about the rotation axis 258 relative to the support member 226. In this respect, the support member 226 may be arranged within the lower chamber 252 of the chamber body 210 and along the rotation axis 258, the support member 226 may couple the susceptor 224 to the shaft member 228, and the shaft member 228 may extend through the lower wall 234 of the chamber body 210 and operably couple the lift and rotate module 220 to the susceptor 224 such that the lift and rotate module 220 may rotate the susceptor 224 about the rotation axis 258 during deposition of the material layer 4 onto the substrate 2.

The susceptor 224 may define one or more lift pin aperture 262, and a lift pin 102 of the lift pin arrangement 100 may be received within the lift pin aperture 262. The lift pin actuator 230 may be arranged (at least in part) within the lower chamber 252 of the chamber body 210 (e.g., about the shaft member 228) and also extend through the lower wall 234 of the chamber body 210. The lift pin actuator 230 may be operably associated with the lift and rotate module 220 for movement between a first position 264 and a second position 266 to seat and unseat substrates (e.g., the substrate 2) from the susceptor 224. When in the first position 264, the lift pin arrangement 100 may dangle from the susceptor 224, the lift pin arrangement 100 spaced apart from the lift pin actuator 230 and carried by the susceptor 224 during rotation about the rotation axis 258. When in the second position 266, the lift pin actuator 230 may abut the lift pin arrangement 100 such that the lift pin 102 protrudes above the susceptor 224. As will be appreciated by those of skill in the art in view of the present disclosure, movement between the first position 264 and the second position 266 may seat and unseat the substrate 2 from the susceptor 224. As will also be appreciated by those of skill in the art in view of the present disclosure, movement between the first position 264 and the second position 266 may also enable the loading and unloading of substrates from the chamber body 210, for example, using the substrate handling transfer robot 270 (e.g., the substrate handling transfer robot 46). As shown and described herein, the reaction chamber 204 includes three (3) lift pins. However, it is to be understood and appreciated that the reaction chamber 204 may have fewer or additional lift pins in other examples and remain within the scope of the present disclosure.

With reference to FIG. 2B, the seating of the substrate 2 within the chamber body 210 is accomplished by opening the gate valve 268 and advancing an end effector 272 into the upper chamber 250 of the chamber body 210 using the substrate handling transfer robot 270 such that the substrate 2 is in registration with the susceptor 224 at a location above the susceptor 224. The lift and rotate module 220 may then translate the lift pin actuator 230 along the rotation axis 258 toward the susceptor 224 between the first position 264 and the second position 266. As the lift pin actuator 230 translates along the rotation axis 258, the lift pin actuator 230 may come into abutment with a lift pin weight 104 supported on the lift pin 102, further translation of the lift pin actuator 230 thereafter driving the lift pin 102 through the susceptor 224 such that the lift pin 102 protrudes above the susceptor 224 and advances upwards within the upper chamber 250 of the chamber body 210. Advancement of the lift pin 102 continues until the lift pin 102 comes into abutment with a lower surface 6 of the substrate 2, subsequent advancement thereafter transferring the substrate 2 to the lift pin arrangement 100. The substrate handling transfer robot 270 then withdraws the end effector 272 from the upper chamber 250 of the chamber body 210.

As shown in FIG. 2C, the lift pin arrangement 100 generally includes the lift pin 102 and the lift pin weight 104. The lift pin 102 includes a lift pin body 106. The lift pin body 106 defines (or is arranged along) a lift pin axis 108 and is configured to be received within the lift pin aperture 262, extending through the susceptor 224. The lift pin body 106 may further be configured to carry (e.g., support) the lift pin weight 104, and therefore, the lift pin weight 104 may exert a tensile load upon the lift pin body 106. The lift pin body 106 may be formed from an opaque ceramic material 110, for example, a material opaque to electromagnetic radiation within an infrared waveband. The material may have a heat transfer coefficient substantially equivalent to that of the material forming the susceptor 224. Examples of suitable opaque materials include ceramic materials, such as silicon carbide, as well as carbonaceous materials such as glassy carbon. As will be appreciated by those of skill in the art in view of the present disclosure, forming the lift pin body 106 from an opaque ceramic material may limit temperature variation across the substrate 2, promoting uniformity of the material layer 4. Advantageously, weighting the lift pin 102 with the lift pin weight 104 tends to both (a) center the lift pin body 106 within the lift pin aperture 262 such that the lift pin axis 108 remains parallel to the rotation axis 258 as well as (b) promote seating of the lift pin 102 within the susceptor 224, for example by opposing horizontal force components exerted on the lift pin body 106 by the substrate 2 and/or by increasing downward force on the lift pin body 106 during withdrawal of the lift pin actuator 230.

In certain examples, the lift pin body 106 may extend axially between a first end 120 and an axially opposite second end 122 and may further have a stem segment 126, a neck segment 128, and a span feature 130. The contact pad 124 may be defined at the first end 120 of the lift pin body 106 and configured to seat and unseat the substrate 2 (shown in FIGS. 2A and 2B) from the susceptor 224 (shown in FIGS. 2A and 2B). The stem segment 126 may extend axially from the contact pad 124 and couple the neck segment 128 and the span feature 130 to the contact pad 124. The neck segment 128 may extend from the stem segment 126 and couple the span feature 130 to the stem segment 126 of the lift pin body 106. The span feature 130 may be defined at a second end 122 of the lift pin body 106 and be connected to the contact pad 124 by the neck segment 128 and the stem segment 126 of the lift pin body 106.

FIG. 3 is a flowchart describing an example method 300 of teaching substrate handling in a semiconductor processing system (e.g., the semiconductor processing system 10 of FIG. 1) in accordance with one or more embodiments of the disclosure. The steps in the method 300 may be performed by a controller (e.g., the controller 18) coupled to the semiconductor processing system. The example steps in FIG. 3 may be performed in different orders and with different, fewer, or additional steps than those illustrated. Some steps may be omitted, while multiple steps may be combined.

As shown in FIG. 3, step 302 of method 300 may include providing a substrate (e.g., the substrate 2) in a reaction chamber (e.g., one of the reaction chambers 16 or the reaction chamber 204) of a semiconductor processing system. The substrate may be provided inside the reaction chamber by transferring the substrate from a substrate handling chamber (e.g., the substrate handling chamber 44 from FIG. 1) to the reaction chamber. The controller of the semiconductor processing system may send instructions to a substrate handling transfer robot (e.g., the substrate handling transfer robot 46) present inside the substrate handling chamber to transfer the substrate from the substrate handling chamber to the reaction chamber. Alternatively, the controller may send instructions to the substrate handling transfer robot to pick the substrate from a load lock (e.g., the load lock 26) and place the substrate in the reaction chamber.

The substrate used for the method 300 may be a dummy substrate that is different from substrates for fabricating semiconductor devices. The dummy substrate may be composed of a material with low thermal conductivity (e.g., 0.01 to 30 W/mK), high-temperature durability (e.g., such sustain temperatures up to 1000 °C, 1200 °C, 1500 °C, 1700 °C, etc.), and low particle shedding. Example materials for the dummy substrate may comprise fused silica, magnesium oxide, vermiculite, calcium silicate, alumina, polyetheretherketone, and/or glass ceramic.

At step 304, lift pins (e.g., the lift pins 102 or 82) inside the reaction chamber may be controlled by the controller such that the lift pins at least partially support the substrate. For example, when the substrate is provided inside the reaction chamber, the substrate may be seated on a susceptor (e.g., the susceptor 224 in FIG. 2). The controller may send instructions to a lift and rotate module (e.g., the lift and rotate module 220) to lift a lift pin actuator (e.g., the lift pin actuator 230) upward such that the lift pins unseat the substrate from the susceptor. Lifting the lift pin actuator may entail moving the lift pin actuator from a first position (e.g., the first position 264 in FIG. 2A) to a second position (e.g., the second position 266 in FIG. 2A). When the lift pin actuator is at the second position, the lift pin actuator may abut the lift pins such that the lift pins protrude above the susceptor (as shown in FIG. 2B) and the lift pins lift the substrate. The contact pad (e.g., the contact pad 124 shown in FIG. 2C) may be touching the lower surface of the substrate.

In another example, the lift pin actuator may already be at the second position and the lift pins may already be protruding above the susceptor when the substrate is introduced inside the reaction chamber at step 302. The substrate may be placed on top of the contact pads (e.g., the contact pads 124) of the lift pins, and the substrate may be fully supported by the lift pins upon placement in the reaction chamber.

In another example, the lift pin actuator may already be at the first position when the substrate is placed inside the reaction chamber and may remain at the first position during performing of step 306 of FIG. 3. Therefore, the substrate may be in contact with both the susceptor and the contact pads of lifts pins when the substrate is provided inside the reaction chamber at step 302 and during the performing of step 306.

The contact pad of the lift pins may be in contact with the lower surface of the substrate at a contact point on the lower surface of the substrate. In some examples, the contact point of a lift pin may be represented as the center of the circular surface of the contact pad of the lift pin. The contact point of each of the lift pins may be represented by planar x and y coordinates, where the origin of the x and y plane is the center of the susceptor or the substrate.

At step 306, one or more processing conditions may be applied to the reaction chamber hosting the substrate. The processing conditions may be the same processing conditions used for processing substrates. For example, the reaction chamber may be placed under increased temperature conditions, increased pressure conditions, or under vacuum. Processing conditions to be applied at step 306 may depend on which process is used. For example, the processing conditions may conform with conditions imposed on reaction chambers for purposes of performing ALD or etching on substrates. The process condition may include the substrate being heated to an elevated temperature (e.g., 200-1000 degrees Celsius), an elevated pressure level inside (e.g., 0.1 to 10 Torr) in the reaction chamber, or the reaction chamber being under a certain vacuum level. The applied processing conditions may have an effect on one or more points within the reaction chamber. For example, the process condition may move the susceptor and/or the lift pins by an offset. The offset may be on the order of millimeters or greater, which would have an adverse effect on semiconductor processing. When the processing conditions are applied to the reaction chamber, the temperature of the lift pins may be elevated, and each of the lift pins may leave a thermal imprint on the substrate.

At step 308, the substrate at the elevated temperature may be transferred from the reaction chamber to a second chamber of the semiconductor processing system, where the second chamber may be coupled to a thermal camera. The second chamber may be the substrate handling chamber (e.g., the substrate handling chamber 44), a load lock (e.g., the load lock 26), a front-end module (e.g., the front-end module 12), or a pod (e.g., the pod 28). For example, the substrate handling robot may pick the substrate from the reaction chamber and bring the substrate to the substrate handling chamber. The substrate handling chamber may be coupled to a thermal camera (e.g., the thermal camera 92 as shown in FIG. 1B). As another example, the substrate handling robot may pick the substrate from the reaction chamber and deposit the substrate in a load lock of the semiconductor processing system. Then, the front-end transfer robot may transfer the substrate from the load lock to a pod of the semiconductor processing system. The pad may be coupled to a thermal camera (e.g., the thermal camera 90 in FIG. 1B).

In some examples, the second chamber may be selected based on the thermal diffusivity of the substrate. For example, if the thermal diffusivity of the substrate is high, then the available time for capturing an accurate thermal image may be short. Therefore, the substrate handling chamber 44 may be selected as the second chamber as the substrate handling chamber 44 is adjacent to the reaction chamber 16. If the thermal diffusivity of the substrate is low, the thermal imprint left on the substrate by the lift pins may sustain itself until the substrate reaches the pod 28 from the reaction chamber. In this case, the second chamber may be the pod 28.

At step 310, a thermal image of the substrate may be captured in the second chamber by the thermal camera coupled to the second chamber. For example, the substrate handling robot may be holding the substrate under the thermal camera in the substrate handling chamber, and the thermal camera may capture a thermal image of the top surface of the substrate by measuring the IR radiations emitting from different portions of the substrate. Alternatively, the substrate may be positioned in the pod, and the thermal camera coupled with the pod may capture a thermal image of the lower surface of the substrate by measuring the IR radiations emitting from different portions of the substrate.

At step 312, the contact points between the substrate and the lift pins, when the substrate was in the reaction chamber, may be determined from the thermal image. The contact points may be assumed to be the center point of the circular surface of the contact tabs of the lift pins. The contact points may be represented as pixels in the thermal image. Other example representations of the contact point may include x and y coordinates in the thermal image, x and y coordinates relative to a center of the susceptor in the image, etc. Step 312 is described in more detail in the description of FIGS. 4 and 7.

At step 314, a substrate handling robot may be taught to place other substrates in the reaction chamber based on the contact points determined from step 312. For example, the controller may comprise a substrate positioning program that may include program code for controlling the substrate handling robot and components of the reaction chamber that are used to load the substrate onto the susceptor. The substrate positioning program may include program code for controlling the spacing between the substrate and other parts of the reaction chamber, such as the center of the susceptor, the edges of the susceptor, the lift pins, etc. The contact points may be provided to the substrate positioning program such that when the substrate positioning program is executed, the substrate handling robot may correctly place other substrates in the reaction chamber.

In some examples, the method 300 may be performed for one set of processing conditions (e.g., the temperature of the reaction chamber at 350 °C and the pressure inside the reaction chamber at 5 Torr). However, the method 300 may be repeated for other sets of processing conditions.

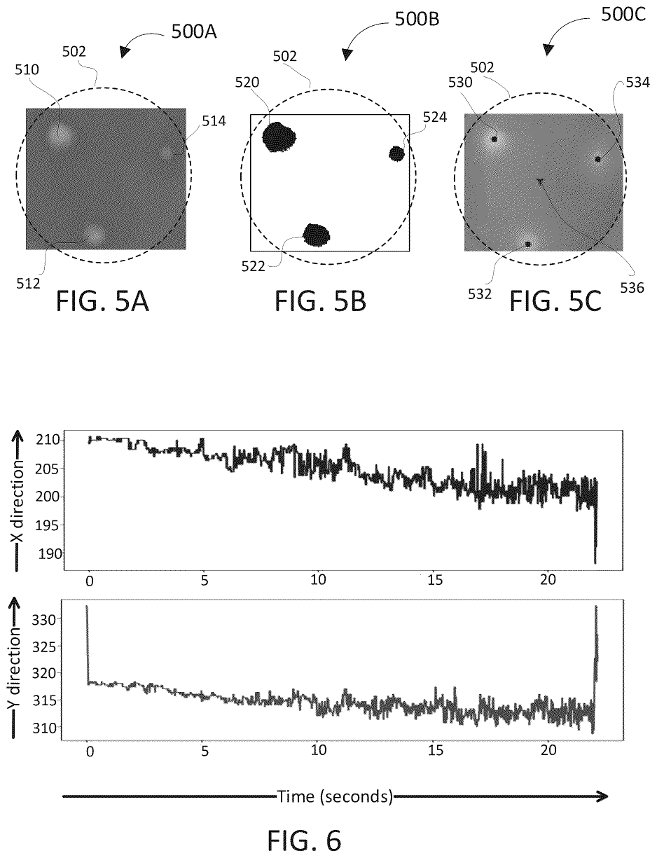

FIG. 4 is a flowchart illustrating an example method of performing step 312 of the method 300 in FIG. 3, where contact points between a substrate (e.g., the substrate 2) and lift pins (e.g., the lift pins 102, 82) when the substrate is in a reaction chamber (e.g., reaction chamber 16) may be determined from the thermal image captured at step 310 of FIG. 3. In some examples, the captured thermal image may be a grayscale image, such as the greyscale image 500A in FIG. 5A. Grayscale images may be represented using shades of grey, where each pixel has only one temperature value corresponding to its brightness or shade of grey. In a grayscale image, higher temperatures may be represented by lighter sages of grey, while darker shades of grey may represent lower temperatures. For example, in the greyscale image 500A, thermal imprints 510, 512, and 514 left by the lift pins on the substrate may be represented by the areas of lighter shades of grey. The thermal imprints may be the areas of higher temperatures on the substrate relative to the rest of the portion of the substrate because of the contact between the substrate and the contact pads (e.g., the contact pads 124) of the lift pins. Circle 502 may represent an estimated outline or circular edge of the substrate based on the shadings in the thermal image or by calculation.

In examples where the captured images are in greyscale, step 402 may be omitted. However, in examples where the captured images are in color, the color image may be converted to a greyscale image before proceeding to step 404. The pixels in a color image may comprise red, green, and blue (RGB) values. Converting a color image to a grayscale image may involve reducing the color information in the RGB values to a single intensity value that represents the brightness of each pixel. One example method of converting a color image to grayscale is by using a weighted average of the RGB values.

At step 404, the thermal image in grayscale format may be binarized. During the binarization process of the thermal image, pixels in the thermal image may be converted into a binary format, where each pixel is classified into one of two categories: hot or cold. The goal of this step may be to simplify the image by distinguishing specific high-temperature regions from the background, making it easier to identify the thermal imprints left by the lift pins. The binarization process may include selecting a threshold value that separates hot regions from cold regions. For example, for a substrate with temperatures at different portions ranging from 200 to 250 °C, the threshold temperature may be at 240 °C. FIG. 5B shows an example binarized image 500B of the greyscale image 500A in FIG. 5A. The clusters of black points 520, 522, and 524 may constitute hot regions where the temperature is above the threshold value, and the white region may be the cold region where the temperature is below the threshold value.

Referring back to FIG. 4, at step 406, each of the clusters of points may be associated with one of the multiple lift pins in the reaction chamber. For example, the greyscale image 500A may be a thermal image of a substrate that was supported by three lift pins in the reaction chamber. The cluster of black points 520 may be associated with the first lift pin in the reaction chamber, the cluster of black points 522 may be associated with a second lift pin in the reaction chamber, and the cluster of black points 524 may be associated with a third lift pin in the reaction chamber.

Referring back to FIG. 4, at step 408, a pixel with the highest temperature may be selected from each cluster of black points 520, 522, and 524. In some examples, two or more pixels from a cluster of points may have the same highest temperature, and a rounded-off average of the two or more pixels may be taken as the selected pixel. Image 500C of FIG. 5C illustrates a selected pixel 530 for the cluster of black points 520, a selected pixel 532 for the cluster of black points 522, and a selected pixel 534 for the cluster of black points 524. At step 410, the coordinates of the selected pixels from step 408 may be selected as the coordinates for the contact points of the lift pins. For example, the coordinates of the selected pixel 530 may be the coordinates of the first lift pin, the coordinates of the selected pixel 532 may be the coordinates of the second lift pin, and the coordinates of the selected pixel 534 may be the coordinates of the third lift pin. The contact point may represent the center of the contact pad of the lift pins. In some examples, a center point 536 of the susceptor may be estimated from the selected pixels 530, 532, and 534.

FIG. 6 illustrates example movements over time of a contact point of a lift pin determined by the example method of FIG. 4. The thermal imprint left on the substrate by the lift pins may move or diffuse over time. Therefore, the pixel representing the highest temperature may also change over time. As shown in FIG. 7, the point with the highest temperature may shift by 6-8 pixels in the x direction or shift by 5-6 pixels within 10 seconds. Therefore, there may be a risk that the contact points determined by the algorithm in FIG. 4 may become less accurate as time elapses.

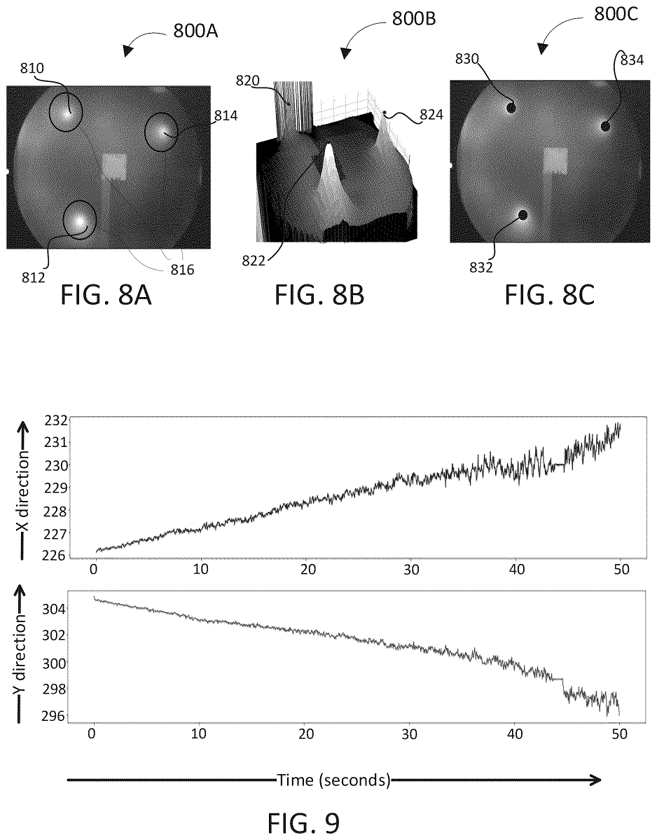

FIG. 7 is a flowchart illustrating another algorithm for performing step 312 of the method 300 in FIG. 3, where contact points of a substrate and lift pins, when the substrate is in a reaction chamber, may be determined from the thermal image captured at step 310 of FIG. 3. Greyscale image 800A in FIG. 8A may be an example greyscale image processed by the algorithm described in FIG. 7. In the greyscale image 800A, thermal imprints 810, 812, and 814 left by the lift pins on the substrate may be represented by the areas of lighter shades of grey. In some examples, the captured thermal images may be color images, and the color images may be converted to a greyscale image before processing the image per the algorithm in FIG. 7. In some examples, the algorithm in FIG. 7 may be applied to the entire image. In other examples, regions 816 containing the thermal imprints 810, 812, and 814 may be identified, and the algorithm may be applied to the regions 816.

At step 702, a thermal profile, such as the thermal profile 800B in FIG. 8B representing the numerical mapping of the temperature distribution across the substrate, may be generated from the thermal image. As discussed above, the thermal image may contain pixel intensities that correspond to the temperature at each point on the substrate. These temperature values may be usually represented in the grayscale image, where the intensity, brightness, or shade of grey of each pixel corresponds to the temperature value at the corresponding portion of the substrate.

Referring back to FIG. 7, at step 704, Gaussian fitting may be applied to the thermal profile of step 702 to identify one or more peaks in the temperature distribution. Gaussian fitting is a statistical method used to fit data points to a Gaussian (normal) distribution curve, which is commonly used in various fields such as signal processing, spectroscopy, and image analysis. One of its primary applications is to detect peaks in noisy data in data sets that follow a bell-shaped distribution. At step 704, a Gaussian function is used to model the distribution of temperature values around the thermal imprints left on the substrate by each lift pin, and the peaks (e.g., maximum points) are identified as the local maxima of this Gaussian function. For example, as shown in FIG. 8B, peaks 820, 822, and 824 may be identified from the thermal profile 800B.

Referring back to FIG. 7, at step 706, the peaks from step 704 may be selected as the coordinates for the contact points of the lift pins. For example, as shown in image 800C in FIG. 8C, for a reaction chamber with three lift pins, the coordinates of the peak 820 may be the coordinates of the contact point 830 of the first lift pin, the coordinates of the peak 822 may be the coordinates of the contact point 832 of the second lift pin, and the coordinates of the peak 824 may be the coordinates of the contact point 834 of the third lift pin. The contact point may represent the center of the contact pad of the lift pins.

FIG. 9 illustrates an example movement over time of a contact point of a lift pin determined by the example method of FIG. 7. As discussed above, the thermal imprint left on the substrate by the lift pins may move or diffuse over time, and therefore, the peaks from the Gaussian fitting may also change over time. As shown in FIG. 9, a peak identified by Gaussian fitting may shift by 1 pixel in the x direction and/or shift 1 pixel in 10 seconds. Therefore, the algorithm for finding the contact points of the lift pins in FIG. 7 may become more accurate than the algorithm in FIG. 4.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method for teaching substrate handling in a semiconductor processing system, comprising:
providing a substrate inside a reaction chamber comprising a plurality of lift pins, wherein each lift pin of the plurality of lift pins is in contact with the substrate at a contact point on the substrate;
applying one or more processing conditions to the reaction chamber;
capturing, via a thermal camera, a thermal image of the substrate;
determining, based on analyzing the thermal image, the contact point for each lift pin of the plurality of lift pins; and
training, based on the contact point for each lift pin of the plurality of lift pins, a substrate handling robot to place another substrate in the reaction chamber.

2. The method of claim 1, wherein the capturing of the thermal image of the substrate comprises:
transferring the substrate from the reaction chamber to a substrate handling module of the semiconductor processing system; and
capturing, in the substrate handling module, the thermal image.

3. The method of claim 1, wherein the capturing of the thermal image of the substrate comprises:
transferring the substrate from the reaction chamber to a front-end module of the semiconductor processing system; and
capturing, in the front-end module, the thermal image.

4. The method of claim 1, wherein the capturing of the thermal image of the substrate comprises:
selecting, based on a thermal diffusivity of the substrate, a second chamber in the semiconductor processing system;
transferring the substrate from the reaction chamber to the second chamber; and
capturing, in the second chamber, the thermal image.

5. The method of claim 1, wherein the thermal camera is disposed above an upper surface of the substrate.

6. The method of claim 1, wherein the thermal camera is disposed below a lower surface of the substrate.

7. The method of claim 1, wherein the thermal image of the substrate comprises a plurality of pixels that corresponds to a plurality of portions on the substrate; and
wherein each pixel of the plurality of pixels represents a temperature of a corresponding location of the plurality of portions.

8. The method of claim 7, wherein the determining of the contact point for each lift pin of the plurality of lift pins comprises:
binarizing the thermal image to identify a cluster of pixels, from the plurality of pixels, associated with the lift pin;
selecting, from the cluster of pixels, a pixel representing a highest temperature from temperatures represented by the cluster of pixels; and
determining the contact point of the lift pin to be the corresponding location, of the plurality of portions, associated with the selected pixel.

9. The method of claim 7, wherein the thermal image comprises a color image; and
wherein the determining of the contact point for each lift pin of the plurality of lift pins comprises:
converting the color image to a grayscale image;
binarizing the grayscale image to identify a cluster of pixels, from the plurality of pixels, associated with the lift pin;
selecting, from the cluster of pixels, a pixel representing a highest temperature among temperatures represented by the cluster of pixels; and
determining the contact point of the lift pin to be the corresponding location, of the plurality of portions, associated with the selected pixel.

10. The method of claim 7, wherein the determining of the contact point for each lift pin of the plurality of lift pins comprises:
Gaussian fitting at least a portion of the plurality of pixels to identify a peak pixel associated with the lift pin; and
determining the contact point of the lift pin to be the corresponding location of the plurality of portions, associated with the identified peak pixel.

11. The method of claim 1, wherein the contact point of each lift pin of the plurality of lift pins comprises x and y coordinates on an upper surface or a lower surface of the substrate.

12. The method of claim 1, wherein, inside the reaction chamber, each lift pin of the plurality of lift pins is in contact with the substrate via a contact tab of the lift pin; and
wherein the contact point of each lift pin of the plurality of lift pins comprises a center point of the contact tab of the lift pin.

13. The method of claim 1, wherein the one or more processing conditions comprise at least one of a temperature level inside the reaction chamber or a pressure level inside the reaction chamber.

14. A semiconductor processing system comprising:
a reaction chamber comprising a plurality of lift pins;
a substrate handling module;
a thermal camera coupled to the substrate handling module;
a substrate handling robot configured to transfer substrates from and to the reaction chamber; and
one or more controllers configured to:
provide a substrate inside the reaction chamber, wherein each lift pin of the plurality of lift pins is in contact with the substrate at a contact point on the substrate;
apply one or more processing conditions to the reaction chamber;
transfer the substrate from the reaction chamber to the substrate handling module;
capture, in the substrate handling module and via the thermal camera, a thermal image of the substrate;
determine, based on analyzing the thermal image, the contact point for each lift pin of the plurality of lift pins; and
train, based on the contact point for each lift pin of the plurality of lift pins, the substrate handling robot to place another substrate in the reaction chamber.

15. The semiconductor processing system of claim 14, wherein the thermal image of the substrate comprises a plurality of pixels that corresponds to a plurality of portions on the substrate; and
wherein each pixel of the plurality of pixels represents a temperature of a corresponding location of the plurality of portions.

16. The semiconductor processing system of claim 15, wherein the one or more controllers are configured to determine the contact point for each lift pin of the plurality of lift pins by:
binarizing a color version of the thermal image or a grayscale version of the thermal image to identify a cluster of pixels, from the plurality of pixels, associated with the lift pin;
selecting, from the cluster of pixels, a pixel representing a highest temperature among temperatures represented by the cluster of pixels; and
determining the contact point of the lift pin to be the corresponding location, of the plurality of portions, associated with the selected pixel.

17. The semiconductor processing system of claim 15, wherein the one or more controllers are configured to determine the contact point for each lift pin of the plurality of lift pins by:
Gaussian fitting at least a portion of the plurality of pixels to identify a peak pixel associated with the lift pin; and
determining the contact point of the lift pin to be the corresponding location of the plurality of portions, associated with the identified peak pixel.

18. The semiconductor processing system of claim 14, wherein the thermal camera is disposed above an upper surface of the substrate.

19. A semiconductor processing system, comprising:
a reaction chamber comprising a plurality of lift pins;
a front-end module;
a thermal camera coupled to the front-end module;
a substrate handling robot configured to transfer substrates from and to the reaction chamber; and
one or more controllers configured to:
provide a substrate inside the reaction chamber, wherein each lift pin of the plurality of lift pins is in contact with the substrate at a contact point on the substrate;
apply one or more processing conditions to the reaction chamber;
transfer the substrate from the reaction chamber to the front-end module;
capture, in the front-end module and via the thermal camera, a thermal image of the substrate;
determine, based on analyzing the thermal image, the contact point for each lift pin of the plurality of lift pins; and
train, based on the contact point for each lift pin of the plurality of lift pins, the substrate handling robot to place another substrate in the reaction chamber.

20. The semiconductor processing system of claim 19, wherein the thermal image of the substrate comprises a plurality of pixels that corresponds to a plurality of portions on the substrate; and
wherein each pixel of the plurality of pixels represents a temperature of a corresponding location of the plurality of portions; and
wherein the one or more controllers are configured to determine the contact point for each lift pin of the plurality of lift pins by:
Gaussian fitting at least a portion of the plurality of pixels to identify a peak pixel associated with the lift pin; and
determining the contact point of the lift pin to be the corresponding location of the plurality of portions, associated with the identified peak pixel.
